(19) United States
(12) Patent Application Publication
(10) Pub. No.: US 2026/0205065 A1
(43) Pub. Date: Jul. 16, 2026

(54) Auto Zero Circuit for a Current Sense Amplifier

(71) Applicant: TEXAS INSTRUMENTS INCORPORATED, Dallas, TX (US)

(72) Inventors: Neeraj Keskar, Allen, TX (US); Tanner Tengberg, Allen, TX (US); Saurav Bandyopadhyay, Dallas, TX (US); Nilanjan Pal, Dallas, TX (US)

(21) Appl. No.: 19/018,347

(22) Filed: Jan. 13, 2025

(51) Int. Cl. H03F 3/04; H03M 1/66

(52) U.S. Cl. CPC H03F 3/04; H03M 1/66

(57) ABSTRACT

An apparatus includes a current sense amplifier having an output. The current sense amplifier includes a resistor coupled to the output. The current sense amplifier is configured to produce a current through the resistor. An auto zero circuit has an input coupled to the output of the current sense amplifier. The auto zero circuit is configured to iteratively adjust a second current from the output of the current sense amplifier through the auto zero circuit based on a voltage across the resistor.

### BACKGROUND

A current sense amplifier is an amplifier that is usable to sense current through, for example, a power stage of a switching converter. One type of current sense amplifier detects the voltage drop across a current-carrying switch (e.g., a transistor) as a technique to sense the current. Achieving sufficient sensing accuracy for a given application can be difficult given variations in process, voltage, and temperature.

### SUMMARY

In one example, an apparatus includes a current sense amplifier having an output. The current sense amplifier includes a resistor coupled to the output. The current sense amplifier is configured to produce a current through the resistor. An auto zero circuit has an input coupled to the output of the current sense amplifier. The auto zero circuit is configured to iteratively adjust a second current from the output of the current sense amplifier through the auto zero circuit based on a voltage across the resistor.

In another example, an apparatus includes a first current source circuit having a first terminal and a second terminal. A voltage-controlled current source circuit has a third terminal, a fourth terminal, and a control input. The third terminal is coupled to the first terminal, and the fourth terminal is coupled to the second terminal. A charge pump circuit has an output coupled to the control input.

In yet another example, an apparatus includes a first current source circuit having a first terminal and a second terminal. A digital-to-analog converter (DAC) has a third terminal, a fourth terminal, and a control input. The third terminal is coupled to the first terminal, and the fourth terminal is coupled to the second terminal. A counter has an output coupled to the control input.

### BRIEF DESCRIPTION OF THE DRAWINGS

FIG. 1 is a schematic diagram of a switching converter including a pulse width modulation (PWM) controller coupled to a high side (HS) transistor and to a low side (LS) transistor and having a current sense amplifier (CSA) with an auto zero circuit, in an example.

FIG. 2 is a schematic diagram of CSA with an auto zero circuit, in an example.

FIG. 3 is a schematic diagram of CSA with the auto zero circuit of FIG. 2 and including additional detail for the auto zero circuit, in an example.

FIG. 4 is a schematic diagram of CSA with the auto zero circuit of FIG. 3 and including yet additional detail for the auto zero circuit, in an example.

FIG. 5 is a schematic diagram of the CSA with the auto zero circuit of FIG. 2 implemented with a different auto zero circuit than in FIGS. 3 and 4, in an example.

### DETAILED DESCRIPTION

The same reference numbers or other reference designators are used in the drawings to designate the same or similar (either by function and/or structure) features.

The examples described herein pertain to an auto zero circuit usable with a current sense amplifier to eliminate most or all of the offsets within the current sense amplifier thereby increasing the accuracy of the current sense amplifier. The current sense amplifier and accompanying auto zero circuit are described herein in the context of a switching converter but can be used to sense current in other applications.

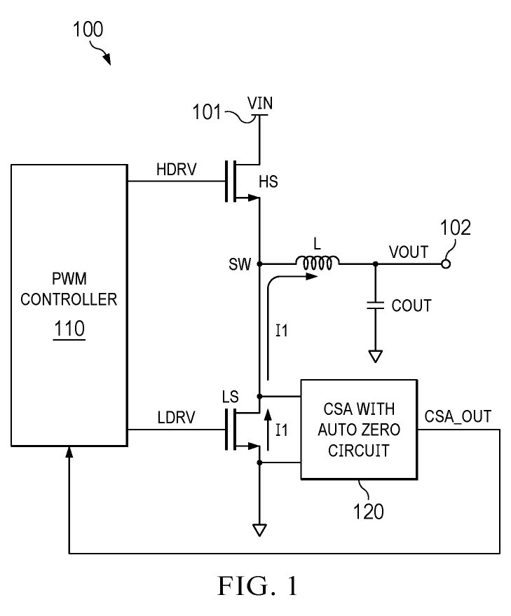

FIG. 1 is a schematic diagram of a switching converter 100 including a pulse width modulation (PWM) controller 110 coupled to a high side (HS) transistor and a low side (LS) transistor. The HS and LS transistors may be implemented as field effect transistors. The PWM controller 110 has outputs that are coupled to the gates of the HS and LS transistors. PWM controller 110 provides a signal HDRV to turn on and off the HS transistor and a signal LDRV to turn on and off the LS transistor. In the example of FIG. 1, the source of the HS transistor is coupled to the drain of the LS transistor at a switching terminal (SW). The switching terminal SW is coupled to one terminal of an inductor L1, and the other terminal of inductor L1 is coupled to a capacitor COUT and to an output terminal 102 (VOUT) of the switching converter 100. The drain of the HS transistor is coupled to an input terminal 101 and receives an input voltage VIN. A current sense amplifier (CSA) with auto zero circuit 120 is coupled across the drain and source of the LS transistor. In the example of FIG. 1, switching converter 100 is a buck converter. The CSA with auto zero circuit 120 can be used with other types of switching converters such as boost converters and buck-boost converters.

CSA with auto zero circuit 120 detects the voltage across the LS transistor. When on, current I1 flows through the on-resistance of the LS transistor thereby producing a voltage drop between the source and drain. The voltage drop is proportional to current I1. CSA with auto zero circuit 120 generates a signal CSA_OUT based on the voltage drop across the LS transistor. In one example, signal CSA_OUT is a voltage that is proportional to current I1.

The auto zero functionality of CSA with auto zero circuit 120 reduces the offset otherwise present within the CSA. Such offset reduction is performed during the on-phase of the HS transistor when the LS transistor is otherwise off. Attempts to determine the amount of offset present in the CSA when the LS transistor is off can be a significant challenge at high switching frequencies and low duty cycles of the switching converter. At high switching frequencies and/or low duty cycles, the HS transistor is on for such a short enough period of time that it can be difficult to determine and correct the offset to be eliminated within the CSA. The CSA with auto zero circuit 120, however, can determine and correct the offset within the CSA over multiple switching cycles thereby eliminating the time constraint of the on-phase of the HS transistor within a single switching cycle.

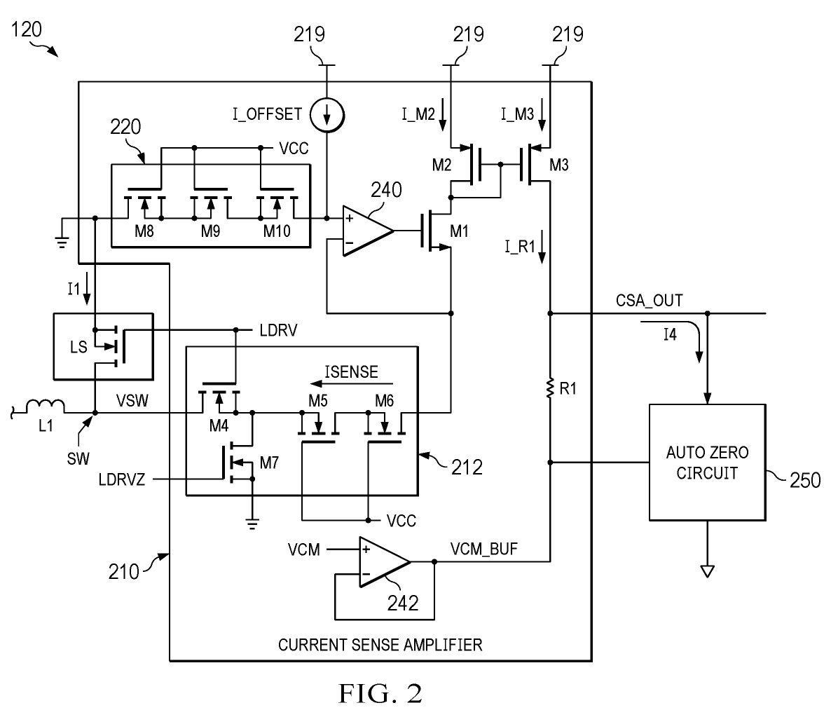

FIG. 2 is a schematic diagram of CSA with auto zero circuit 120, in an example. CSA with auto zero circuit 120 includes a current sense amplifier 210 coupled to an auto zero circuit 250. Current sense amplifier 210 includes current sense transistors 212, offset transistors 220, a current source circuit I_OFFSET, amplifiers 240 and 242 (e.g., operation amplifiers), transistors M1, M2, and M3, and resistor R1. Current sense transistors 212 include transistors M4, M5, M6, and M7. Offset transistors 220 include transistors M8, M9, and M10. Although four transistors M4-M7 are included in current sense transistors 212 in the example of FIG. 2, a different number than four transistors can be included in other examples. Similarly, a different number than three transistors can be included in offset transistors 220 in other examples.

Transistors M1 and M4-M10 are n-channel field effect transistors (NFETs) and transistors M2 and M3 are p-channel field effect transistors (PFETs) in the example of FIG. 2 but can be other types of transistors in other examples. The drain of transistor M4 is coupled to switching terminal SW, and the source of transistor is coupled to the source of transistor M5 and to the drain of transistor M7. The source of transistor M7 is coupled to ground. the drain of transistor M5 is coupled to the source of transistor M6, and the drain of transistor M6 is coupled to the negative input of amplifier 240 and to the source of transistor M1. The gate of transistor M4 is coupled to the gate of the LS transistor. The gate of transistor M7 receives the logical inverse of signal LDRV (signal LDRVZ). The gates of transistors M5 and M6 are coupled together and to a fixed bias voltage VCC.

Transistors M2 and M3 are coupled together to form a current mirror. Their sources are coupled together and to the supply voltage terminal 219. The drain of transistor M1 is coupled to the drain of transistor M2 and to the gates of transistors M2 and M3. One terminal of resistor R1 is coupled to the drain of transistor M3, and the other terminal of resistor R1 is coupled to the output and negative input of amplifier 242. The positive input of amplifier 242 receives a common mode voltage VCM. Amplifier 242 is configured as a unity gain buffer and generates a common mode voltage VCM_BUF at its output.

Current I1 flowing through the LS transistor causes the voltage Vsw at the switching terminal SW to be equal to –(I1 x Rdson_LS) (a negative value), where Rdson_LS is the on-resistance of the LS transistor. Accordingly, voltage Vsw is proportional to current I1, which is the current to be sensed by current sense amplifier 210.

Transistors M8-M10 are coupled in series between ground and the positive input of amplifier 240. Current source circuit I_OFFSET is coupled between a supply voltage terminal 219 and the drain of transistor M10. The gates of transistors M8-M10 are coupled together and receive the fixed bias voltage VCC. Current (also called current (I_OFFSET)) from source circuit I_OFFSET flows through the series combination of transistors M8-M10 to ground. Each transistor M8-M10 has an on-resistance. With current I_OFFSET flowing through transistors M8-M10, the voltage drop between ground and the positive input of amplifier 240 is I_OFFSET x 3(Rdson), where “Rdson” is the on-resistance of each of transistors M8-M10.

Ignoring the offset transistors 220 and current source circuit I_OFFSET for a moment and assuming the positive input of amplifier 240 is coupled to ground and assuming amplifier 240 is an ideal operational amplifier (e.g., having no offset voltage), the voltage at the negative input of amplifier 240 also is ground. With the voltage at the drain of transistor M4 being –(I1 x Rdson_LS), current ISENSE flows from the source of transistor M1 and through transistors M6, M5, and M4 to the switching terminal SW. Because the voltage Vsw is proportional to current I1, current ISENSE also is proportional to current I1. Current ISENSE, which also is current I_M2, is mirrored through the mirror formed by transistors M2 and M3 (e.g., a 1:1 current mirror ratio) as current I_M3. Current I_M3 flows through resistor R1 thereby generating the signal (e.g., voltage) CSA_OUT.

Current sense amplifier 210 generates signal CSA_OUT which is proportional to current I1. However, it may be possible for the current I1 to be negative—flow in the opposite direction from that shown in FIG. 2. If that were to happen, current ISENSE would need to be negative (which it cannot because current through transistor M1 can only flow from drain to source), and signal CSA_OUT will not accurately reflect current I1. To address this potential problem, current source circuit I_OFFSET and offset transistors 220 are included to ensure that the voltage at the negative input of amplifier 240 is more positive than the voltage Vsw would be thereby ensuring that current ISENSE remains positive relative to polarity indicated in FIG. 2 (positive current ISENSE flows from right to left).

Due to the inclusion of current source circuit I_OFFSET, current I_M2 is the sum of currents ISENSE and I_OFFSET. Because current I_M2 is mirrored as current I_M3, current I_M3 also is the sum of currents ISENSE and I_OFFSET. Auto zero circuit 250 determines a current I4 to flow through transistor M3 to ground such that the remaining current I_R1 approximately equals ISENSE. Auto zero circuit 250 determines the magnitude of current I4 over one or more switching cycles of switching converter 100 during the on-phases (HS transistor on) and then subtracts out current I4 during the off-phases (LS transistor on). During the on-phase signal LDRV is logic low thereby turning off transistors M4 and LS, and signal LDRVZ is logic high thereby turning on transistor M7. During the off-phase, signal LDRV is logic high thereby turning on transistors M4 and LS, and signal LDRVZ is logic low thereby turning off transistor M7 and allowing current ISENSE to be proportional to current I1. Auto zero circuit 250 advantageously generates the correct level of current I4 to result in current I_R1 to approximate current I1 despite the various offsets within the current sense amplifier 210. Sources of offset include the offset within amplifier 240 and mismatches between transistors M4-M6 versus transistors M8-M10, and any offset error caused by mismatch between transistors M2-M3.

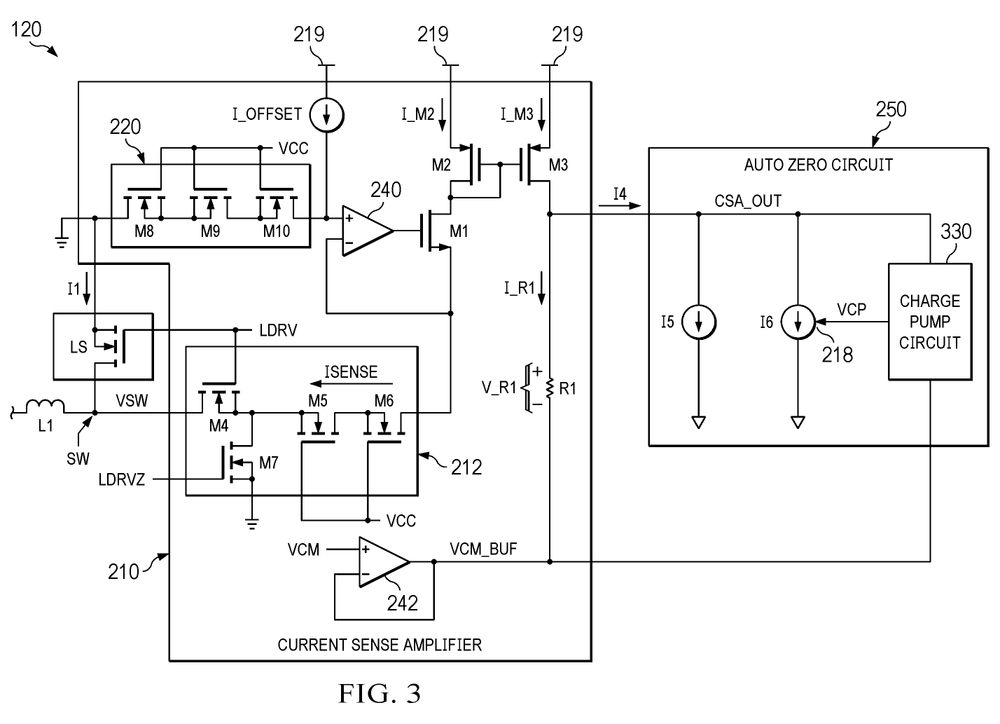

FIG. 3 is another schematic of CSA with auto zero circuit 120 including additional detail for the auto zero circuit 250. In this example, auto zero circuit includes a current source circuit I5 (e.g., a fixed current source circuit), a voltage-controlled current source circuit I6, and a charge pump circuit 330. In one example, current source circuit I5 is configured to produce approximately 75% of the current I_OFFSET. The remaining portion of current I_OFFSET is produced by voltage-controlled current source circuit I6 under control from charge pump circuit 330. During the on-phase (transistor LS off) of the switching converter 100, current ISENSE is approximately 0 amperes and, accordingly, current I_M2 is approximately equal to current I_OFFSET. As such, current I_M3 also is approximately equal to current I_OFFSET. Charge pump circuit 330 generates a voltage VCP to a control input 218 of voltage-controlled current source circuit I6 based on the voltage across resistor R1 (V_R1). Opposing terminals of resistor R1 are coupled to charge pump circuit 330. In an example, charge pump circuit 330 generates the voltage VCP based on the polarity of the voltage across resistor R1. Ideally, the sum of currents I5 and I6 (current I4) is equal to current I_OFFSET during the off-phase. If current I4 is smaller than current I_OFFSET, a positive current I_R1 flows downward through resistor R1. Charge pump circuit 330 responds to the positive voltage V_R1 across resistor R1 by increasing the voltage VCP to the control input 218 of voltage-controlled current source circuit I6, which causes current I6 to increase. If current I4 is still smaller than current I_OFFSET, charge pump circuit 330 further increases voltage. If voltage VCP becomes large enough that current I4 is larger than current I_OFFSET, current I_R1 becomes negative, the polarity of voltage V_R1 inverts, and charge pump circuit 330 responds by decreasing voltage VCP thereby causing voltage-controlled current source circuit I6 to reduce current I6. Charge pump circuit 330 iteratively adjusts voltage VCP during the off-phase of switching converter 100 across multiple switching cycles until current I4 is approximately equal to current I_OFFSET.

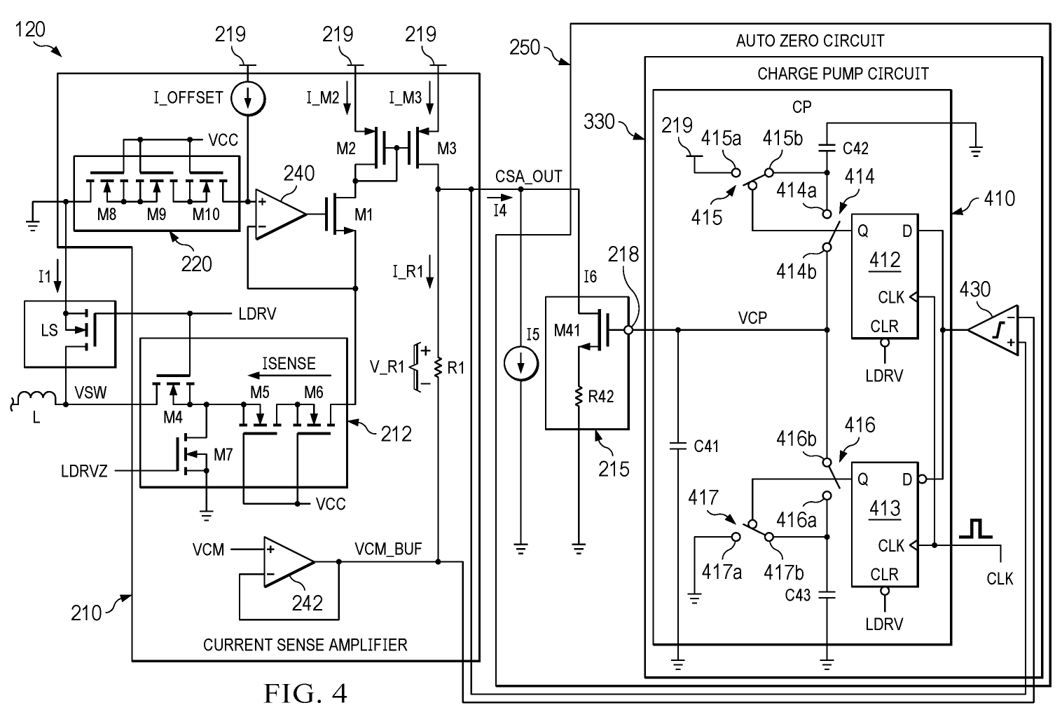

FIG. 4 is another schematic of CSA with auto zero circuit 120 including yet additional detail for auto zero circuit 250. In the example of FIG. 4, voltage-controlled current source circuit I6 includes a transistor M41 (e.g., an NFET) coupled to a resistor R42. The drain of transistor M42 is coupled to the drain of transistor M3 and to resistor R1. Resistor R42 is coupled between the source of transistor M41 and ground. The gate of transistor M41 is coupled to control input 218. The voltage at the source of transistor M41 is based on the voltage VCP applied to the gate of transistor M41 (e.g., the source voltage is a threshold voltage below the gate voltage). The voltage at the source of transistor M41 is applied to resistor R42 thereby setting the current I6 based on the gate voltage, i.e., voltage VCP.

Charge pump circuit 330 includes a charge pump 410 and a comparator 430. The negative input of comparator 430 is coupled to the output of amplifier 242 and to one terminal of resistor R1. The positive input of comparator 430 is coupled to the other terminal of resistor R1. Comparator 430 generates a logic high signal at its output responsive to CSA_OUT being larger than VCM_BUF during HS transistor on-time. Comparator 430 generates a logic low signal at its output responsive to CSA_OUT being smaller than VCM_BUF during HS transistor on-time.

Charge pump 410 includes flip-flops 412 and 413, capacitors C41, C42, and C43, and switches 414, 415, 416, and 417 (e.g., transistors). The output of comparator 430 is coupled to the data (D) inputs of flip-flops 412 and 413, with the D input of flip-flop 413 being logically inverted relative to the D input of flip-flop 412. Each flip-flop 412 and 413 has an active low clear (clr) input which receives the signal LDRV. Flip-flops 412 and 413 are cleared when signal LDRV is logic low thereby forcing their Q outputs to be logic low and causing switches 414-417 to start at a predetermined state each switching cycle of the switching converter 100. A clock CLK is provided to the clock inputs of flip-flops 412 and 413. In one example, clock CLK has the same frequency as the switching frequency of switching converter 100. Each of switches 414-417 has a control input. The control inputs of switches 414 and 415 are coupled to the Q output of flip-flop 412, and the control inputs of switches 416 and 417 are coupled to the Q output of flip-flop 413. The control input of switch 415 is logically inverted relative to the control input of switch 414. Similarly, the control input of switch 417 is logically inverted relative to the control input of switch 416. Accordingly, when the Q output of flip-flop 412 is logic high, switch 414 closes and switch 415 opens, and when the Q output of flip-flop 412 is logic low, switch 414 opens and switch 415 closes. Similarly, when the Q output of flip-flop 413 is logic high, switch 416 closes and switch 417 opens, and when the Q output of flip-flop 413 is logic low, switch 416 opens and switch 417 closes.

Capacitor C42 is coupled between a terminal of 414a of switch 414 and ground. One terminal 415a of switch 415 is coupled to the supply voltage terminal 219, and the opposing terminal 415b is coupled to the capacitor C42. When switch 415 is closed and switch 414 is open, capacitor C42 is charged to the voltage of the supply voltage terminal 219. The opposing terminal 414b of switch 414 is coupled to the gate of transistor M41. Capacitor C41 is coupled between the gate of transistor M41 and ground. Accordingly, when switch 414 closes and switch 415 opens, the charge on capacitor C42 discharges into capacitor C41 thereby causing voltage C41 to increase.

Capacitor C43 is coupled between a terminal of 416a of switch 416 and ground. One terminal 417a of switch 417 is coupled to ground, and the opposing terminal 417b is coupled to capacitor C43. When switch 417 is closed and switch 416 is open, capacitor C43 is discharged at least partially. The opposing terminal 416b of switch 416 is coupled to the gate of transistor M41. Accordingly, when switch 416 closes and switch 417 opens, the charge on capacitor C43 discharges from capacitor C41 thereby causing voltage C41 to decrease. Charge pump 410 can increase the magnitude of voltage VCP by causing charge to be transferred from capacitor C42 to capacitor C41 or decrease the magnitude of voltage VCP by causing capacitor C41 to discharge into capacitor C43.

Comparator 430 causes flip-flops 412 and 413 to control the open and closed states of switches 414-417 based on the polarity of the voltage V_R1 during HS transistor on-time. When the voltage V_R1 is positive, flip-flop 412 outputs a logic high at its Q output and flip-flop 413 outputs a logic low at its output. The logic high at the Q output of flip-flop 412 causes switch 414 to close and switch 415 to open, and the logic low at the Q output of flip-flop 413 causes switch 416 to open and switch 417 to close thereby causing the charge from capacitor C42 to transfer to capacitor C41 and voltage VCP to increase. By contrast, when the voltage V_R1 is negative, flip-flop 412 outputs a logic low at its Q output and flip-flop 413 outputs a logic high at its output. The logic low at the Q output of flip-flop 412 causes switch 414 to open and switch 415 to close, and the logic high at the Q output of flip-flop 413 causes switch 416 to close and switch 417 to open thereby causing the charge from capacitor C41 to transfer to capacitor C43 and voltage VCP to decrease.

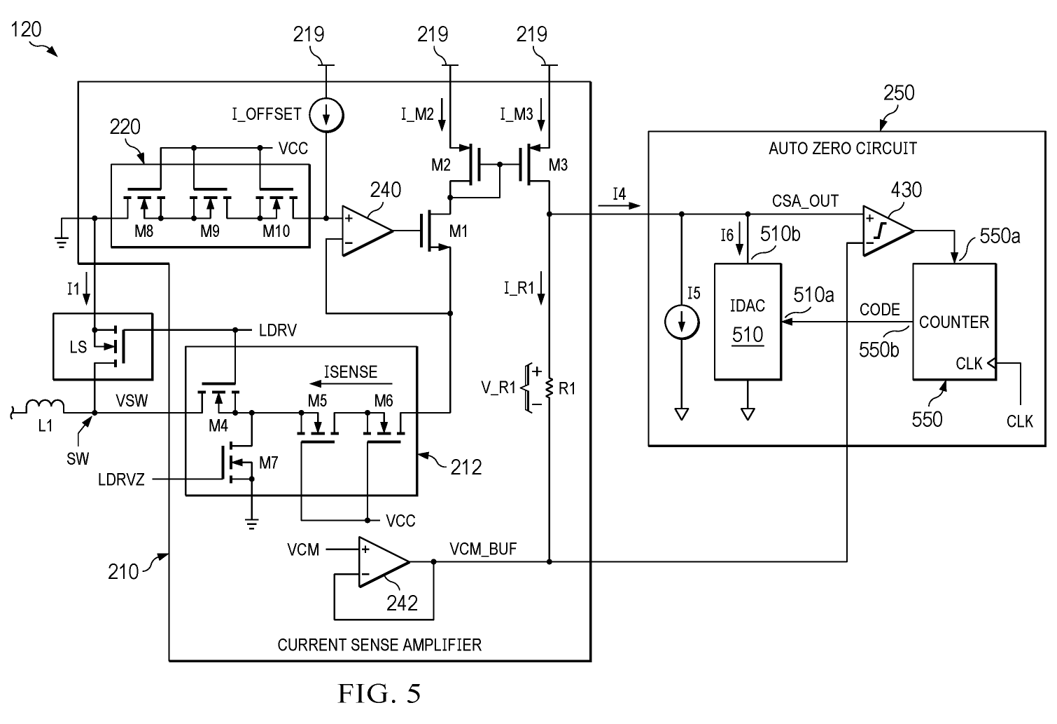

FIG. 5 is a schematic diagram of another example of auto zero circuit 250. In this example, auto zero circuit 250 includes fixed current source circuit I5, a digital-to-analog converter (DAC) 510 (e.g., a current DAC (IDAC)), comparator 430, and a counter 550. In one example, counter 550 is an up/down counter. Comparator 430 compares CSA_OUT to VCM_BUF. The output of comparator 430 is coupled to a control input 550a of counter 550. The logic state (high or low) of the output signal from comparator 430 causes the counter 550 to increment or decrement its output code CODE upon being clocked by clock CLK. The output of counter 550 is coupled to a control input 510a of DAC 510, and the output 510b of DAC 510 is coupled to the drain of transistor M3. DAC 510 generates current I6 at a level based on the output CODE from counter 550. In one example, an increase in the value of CODE causes DAC 510 to increase current I6, and a decrease in the value of CODE causes DAC 510 to decrease current I6. Accordingly, depending on the polarity of voltage V_R1, DAC 510 causes current I6 to increase or decrease.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

Also, in this description, the recitation “based on” means “based at least in part on.” Therefore, if X is based on Y, then X may be a function of Y and any number of other factors.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

As used herein, the terms “terminal”, “node”, “interconnection”, “pin” and “lead” are used interchangeably. Unless specifically stated to the contrary, these terms are generally used to mean an interconnection between or a terminus of a device element, a circuit element, an integrated circuit, a device or other electronics or semiconductor component.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

While the use of particular transistors is described herein, other transistors (or equivalent devices) may be used instead with little or no change to the remaining circuitry. For example, a field effect transistor (“FET”) (such as an n-channel FET (NFET) or a p-channel FET (PFET)), a bipolar junction transistor (BJT – e.g., NPN transistor or PNP transistor), an insulated gate bipolar transistor (IGBT), and/or a junction field effect transistor (JFET) may be used in place of or in conjunction with the devices described herein. The transistors may be depletion mode devices, drain-extended devices, enhancement mode devices, natural transistors or other types of device structure transistors. Furthermore, the devices may be implemented in/over a silicon substrate (Si), a silicon carbide substrate (SiC), a gallium nitride substrate (GaN) or a gallium arsenide substrate (GaAs).

References may be made in the claims to a transistor’s control input and its current terminals. In the context of a FET, the control input is the gate, and the current terminals are the drain and source. In the context of a BJT, the control input is the base, and the current terminals are the collector and emitter.

References herein to a FET being “ON” or “enabled” means that the conduction channel of the FET is present and drain current may flow through the FET. References herein to a FET being “OFF” or “disabled” means that the conduction channel is not present so drain current does not flow through the FET. An “OFF” FET, however, may have current flowing through the transistor’s body-diode.

Circuits described herein are reconfigurable to include additional or different components to provide functionality at least partially similar to functionality available prior to the component replacement. Components shown as resistors, unless otherwise stated, are generally representative of any one or more elements coupled in series and/or parallel to provide an amount of impedance represented by the resistor shown. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

While certain elements of the described examples are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Uses of the phrase “ground” in the foregoing description include a chassis ground, an Earth ground, a floating ground, a virtual ground, a digital ground, a common ground, and/or any other form of ground connection applicable to, or suitable for, the teachings of this description. In this description, unless otherwise stated, “about,” “approximately” or “substantially” preceding a parameter means being within +/- 10 percent of that parameter or, if the parameter is zero, a reasonable range of values around zero.

Modifications are possible in the described examples, and other examples are possible, within the scope of the claims.

What is claimed is:

1. An apparatus, comprising:
a current sense amplifier having an output, the current sense amplifier including a resistor coupled to the output, the current sense amplifier configured to produce a current through the resistor; and
an auto zero circuit having an input coupled to the output of the current sense amplifier, the auto zero circuit configured to iteratively adjust a second current from the output of the current sense amplifier through the auto zero circuit based on a voltage across the resistor.

2. The apparatus of claim 1, wherein the auto zero circuit includes:
a first current source circuit coupled to the input of the auto zero circuit;
a voltage-controlled current source circuit coupled in parallel with the first current source circuit, the voltage-controlled current source circuit having a control input; and
a charge pump circuit coupled to the resistor and having an output coupled to the control input of the voltage-controlled current source circuit.

3. The apparatus of claim 2, wherein the charge pump circuit is configured to adjust a voltage to the control input based on a polarity of the voltage across the resistor.

4. The apparatus of claim 2, wherein the resistor has first and second resistor terminals, and charge pump circuit includes:
a comparator having a first comparator input coupled to the first resistor terminal and having a second comparator input coupled to the second resistor terminal, the comparator having an output; and
a charge pump coupled between the output of the comparator and the control input.

5. The apparatus of claim 2, wherein the resistor is a first resistor, and wherein the voltage-controlled current source circuit includes:
a transistor having first and second terminals and a control terminal, the first terminal of the transistor coupled to the input of the auto zero circuit, and the control terminal of the transistor coupled to the control input of the voltage-controlled current source circuit; and
a second resistor coupled to the second terminal of the transistor.

6. The apparatus of claim 1, wherein the resistor has first and second resistor terminals, and wherein the auto zero circuit includes:
a current source circuit coupled to the input of the auto zero circuit;
a current digital-to-analog converter (IDAC) having a first terminal coupled to the input of the auto zero circuit and having a second terminal;
a comparator having a first comparator input coupled to the first resistor terminal and having a second comparator input coupled to the second resistor terminal, the comparator having an output; and
a counter having an input coupled to the output of the comparator and having an output coupled to the second terminal of the IDAC.

7. The apparatus of claim 6, wherein the counter is an up/down counter.

8. The apparatus of claim 1, wherein the current sense amplifier has first and second terminals, and the apparatus further comprises a transistor having first and second transistor terminals, the first transistor terminal coupled to the first terminal of the current sense amplifier, and the second transistor terminal coupled to the second terminal of the current sense amplifier.

9. The apparatus of claim 8, wherein the current sense amplifier comprises a current source circuit, and the current sense amplifier is configured to flow a current from the current source circuit through the resistor when the transistor is off.

10. An apparatus, comprising:
a first current source circuit having a first terminal and a second terminal;
a voltage-controlled current source circuit having a third terminal, a fourth terminal, and a control input, the third terminal coupled to the first terminal, and the fourth terminal coupled to the second terminal; and
a charge pump circuit having an output coupled to the control input.

11. The apparatus of claim 10, wherein the voltage-controlled current source circuit includes:
a transistor having first and second terminals and a control terminal, the first terminal of the transistor coupled to the third terminal, and the control terminal of the transistor coupled to the control input of the voltage-controlled current source circuit; and
a resistor having first and second terminals, the first terminal of the resistor coupled to the second terminal of the transistor, and the second terminal of the resistor coupled to fourth terminal.

12. The apparatus of claim 11, wherein the charge pump circuit includes:
a comparator having a first comparator input coupled to the first terminal of the first current source circuit, the comparator having an output; and
a charge pump coupled between the output of the comparator and the control input.

13. The apparatus of claim 10, wherein the charge pump circuit includes:
a comparator having a first comparator input coupled to the first terminal of the first current source circuit, the comparator having an output; and
a charge pump coupled between the output of the comparator and the control input.

14. The apparatus of claim 13, wherein the charge pump circuit includes:
a first flip-flop having a first input coupled to the output of the comparator and having a first output;
a first capacitor;
a first switch coupled between the first capacitor and the control input, the first switch having a control terminal coupled to the first output;
a second flip-flop having a second input coupled to the output of the comparator and having a second output;
a second capacitor; and
a second switch coupled between the second capacitor and the control input, the second switch having a control terminal coupled to the second output.

15. The apparatus of claim 14, further comprising a second capacitor having a first terminal coupled to the control input and having a second terminal coupled to the fourth terminal.

16. The apparatus of claim 10, further comprising a current sense amplifier having an output coupled to the first terminal of the first current source circuit and to the third terminal of the voltage-controlled current source circuit.

17. An apparatus, comprising:
a first current source circuit having a first terminal and a second terminal;
a digital-to-analog converter (DAC) having a third terminal, a fourth terminal, and a control input, the third terminal coupled to the first terminal, and the fourth terminal coupled to the second terminal; and
a counter having an output coupled to the control input.

18. The apparatus of claim 17, wherein the counter has an input, and the apparatus further comprises a comparator having an input coupled to the first and third terminals and having an output coupled to the input of the counter.

19. The apparatus of claim 18, wherein the input of the comparator is a first input and the comparator has a second input, and the apparatus further comprises a resistor having first and second terminals, the first terminal of the resistor coupled to the first terminal of the first current source circuit, and the second terminal of the resistor coupled to the second input of the comparator.

20. The apparatus of claim 17, wherein the DAC is a current DAC.
